(19) United States
(12) Patent Application Publication
(10) Pub. No.: US 2025/0006763 A1
(43) Pub. Date: Jan. 2, 2025

(54) IMAGE SENSOR AND METHOD OF FABRICATING THE SAME

(71) Applicant: Samsung Electronics Co., Ltd., Suwon-si (KR)

(72) Inventors: Kook Tae KIM, Suwon-si (KR); Jingyun KIM, Suwon-si (KR); Minkyung LEE, Suwon-si (KR)

(21) Appl. No.: 18/441,681

(22) Filed: Feb. 14, 2024

(30) Foreign Application Priority Data
Jun. 28, 2023 (KR) 10-2023-0083441

(51) Int. Cl. H01L 27/146

(52) U.S. Cl. CPC H01L 27/1463; H01L 27/14627; H01L 27/14629; H01L 27/14645; H01L 27/14683

(57) ABSTRACT

An image sensor includes a substrate that includes a first surface and a second surface that are opposite to each other, where the substrate includes a plurality of pixel areas; an isolation pattern that extends from the first surface and into the substrate, where the isolation pattern is between the plurality of pixel areas; and an antireflection layer on the isolation pattern, where the isolation pattern includes: a first device isolation pattern that contacts the antireflection layer; and a second device isolation pattern that is spaced apart from the antireflection layer, where the first device isolation pattern includes: a first dielectric layer; and a conductive reflection layer on the first dielectric layer, and where a top surface of the conductive reflection layer and a top surface of the first dielectric layer extend from the second surface of the substrate by a same distance.

### CROSS-REFERENCE TO RELATED APPLICATION

This U.S. nonprovisional application claims priority under 35 U.S.C. § 119 to Korean Patent Application No. 10-2023-0083441 filed on Jun. 28, 2023 in the Korean Intellectual Property Office, the disclosure of which is hereby incorporated by reference in its entirety.

### TECHNICAL FIELD

The present disclosure relates to an image sensor and a method of fabricating the same, and more particularly, to a complementary metal oxide semiconductor (CMOS) image sensor and a method of fabricating the same.

### BACKGROUND

An image sensor is a semiconductor device that transforms optical images into electrical signals. Recent advances in computer and communication industries have led to strong demands in high performances image sensors in various consumer electronic devices, such as digital cameras, camcorders, PCSs (Personal Communication Systems), game devices, security cameras, medical micro-cameras, etc. An image sensor can be classified as a charge coupled device (CCD) type or a complementary metal oxide semiconductor (CMOS) type. A CMOS type image sensor may be abbreviated as a CIS (CMOS image sensor). The CIS has a plurality of two-dimensionally arranged pixels. Each of the pixels includes a photodiode (PD). The photodiode transforms an incident light into an electrical signal. The plurality of pixels are defined by a deep isolation pattern disposed therebetween.

### SUMMARY

Some embodiments of the present disclosure provide an image sensor configured to minimize or inhibit the occurrence of dark current and a method of fabricating the same.

Some embodiments of the present disclosure provide an image sensor configured to increase the light reflection efficiency and configured to improve the sensitivity and a method of fabricating the same.

Some embodiments of the present disclosure provide a highly-integrated image sensor and a method of fabricating the same.

According to some embodiments of the present disclosure, an image sensor may comprise: a substrate that includes a first surface and a second surface that are opposite to each other, where the substrate includes a plurality of pixel areas; an isolation pattern that extends from the first surface and into the substrate, where the isolation pattern is between the plurality of pixel areas; and an antireflection layer on the isolation pattern, where the isolation pattern includes: a first device isolation pattern that contacts the antireflection layer; and a second device isolation pattern that is spaced apart from the antireflection layer, where the first device isolation pattern includes: a first dielectric layer; and a conductive reflection layer on the first dielectric layer, and where a top surface of the conductive reflection layer and a top surface of the first dielectric layer extend from the second surface of the substrate by a same distance.

According to some embodiments of the present disclosure, an image sensor may comprise: a substrate that includes a first surface and a second surface that are opposite to each other, where the substrate includes a plurality of pixel areas; an isolation pattern that extends from the first surface and into the substrate, where the isolation pattern is between the plurality of pixel areas; and an antireflection layer on the isolation pattern, where the isolation pattern includes: a first device isolation pattern that contacts the antireflection layer; and a second device isolation pattern that is spaced apart from the antireflection layer, where the first device isolation pattern includes: a first dielectric layer; and a conductive reflection layer on the first dielectric layer, and where the antireflection layer includes: a parallel layer portion that extends in a direction that is parallel to the first surface of the substrate; and a vertical layer portion that extends from the parallel layer portion toward the second surface of the substrate and contacts the conductive reflection layer.

According to some embodiments of the present disclosure, an image sensor may comprise: a substrate that includes a first surface and a second surface that are opposite to each other, where the substrate includes a plurality of pixel areas; a plurality of microlenses on the first surface of the substrate; a transfer gate on the second surface of the substrate; an isolation pattern that extends from the first surface and into the substrate, where the isolation pattern is between the plurality of pixel areas; and an antireflection layer on the isolation pattern, where the isolation pattern includes: a first device isolation pattern that contacts the antireflection layer; and a second device isolation pattern that is spaced apart from the antireflection layer, where the first device isolation pattern includes: a first dielectric layer; and a conductive reflection layer on the first dielectric layer, where the second device isolation pattern includes: a buried layer; a conductive liner on the buried layer; and a dielectric liner on the conductive liner, and where the antireflection layer includes: a parallel layer portion that is parallel to the first surface of the substrate; and a vertical layer portion that extends from the parallel layer portion and toward the second surface of the substrate, where the vertical layer portion contacts the conductive reflection layer.

### BRIEF DESCRIPTION OF DRAWINGS

FIG. 1 illustrates a simplified block diagram of an image sensor according to some embodiments of the present disclosure.

FIG. 2 illustrates a circuit diagram of an active pixel sensor array of an image sensor according to some embodiments of the present disclosure.

FIG. 3 illustrates a plan view of an image sensor according to some embodiments of the present disclosure.

FIG. 4A illustrates a cross-sectional view taken along line A-A′ of FIG. 3.

FIG. 4B illustrates an enlarged view of section M1 of FIG. 4A.

FIG. 4C illustrates a cross-sectional view taken along line B-B′ of FIG. 3.

FIG. 4D illustrates an enlarged view of section M2 of FIG. 4C.

FIG. 5A illustrates a cross-sectional view taken along line A-A′ of FIG. 3 of an image sensor according to some embodiments of the present disclosure.

FIG. 5B illustrates an enlarged view of section M1 of FIG. 5A.

FIG. 5C illustrates a cross-sectional view taken along line B-B′ of FIG. 3 of an image sensor according to some embodiments of the present disclosure.

FIG. 5D illustrates an enlarged view of section M2 of FIG. 5C.

FIGS. 6A, 6B, 7A, 7B, 8A, 8B, 9A, 9B, 10A, 10B, 11A, and 11B illustrate cross-sectional views taken along lines A-A′ and B-B′ of FIG. 3 and of a method of fabricating an image sensor according to some embodiments of the present disclosure.

### DETAILED DESCRIPTION OF EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. The phrase “an element A surrounds element B” may refer to element A at least partially surrounding element B. The phrases “an element A is filled with element B” or “element B fills element A” refer to element B being at least partially in a space defined by element A. As used herein, “an element A is at a same level as element B” refers to at least one surface of element A that is coplanar with at least one surface of element B.

The following will now describe in detail some embodiments of the present disclosure with reference to the accompanying drawings.

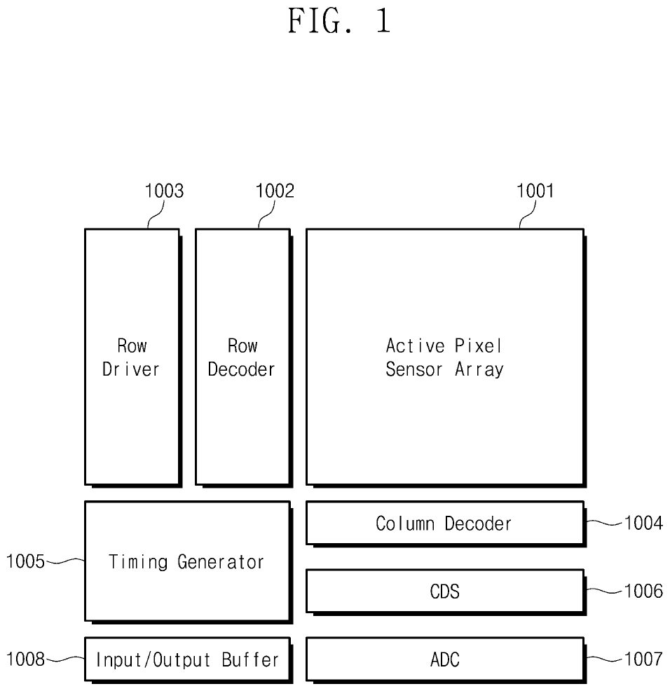

FIG. 1 illustrates a simplified block diagram showing an image sensor according to some embodiments of the present disclosure.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of two-dimensionally arranged unit pixels, each of which is configured to convert optical signals into electrical signals. The active pixel sensor array 1001 may be driven by a plurality of driving signals, such as a pixel selection signal, a reset signal, and a charge transfer signal from the row driver 1003. The correlated double sampler 1006 may receive the converted electrical signals.

The row driver 1003 may provide the active pixel sensor array 1001 with several driving signals for driving several unit pixels in accordance with a decoded result obtained from the row decoder 1002. When the unit pixels are arranged in a matrix shape, the driving signals may be provided for respective rows.

The timing generator 1005 may provide timing and control signals to the row decoder 1002 and the column decoder 1004.

The correlated double sampler 1006 may receive the electrical signals generated by the active pixel sensor array 1001, and may hold and sample the received electrical signals. The correlated double sampler 1006 may perform a double sampling operation to sample a specific noise level and a signal level of the electrical signal, and then may output a difference level corresponding to a difference between the noise and signal levels.

The analog-to-digital converter 1007 may convert analog signals, which correspond to the difference level received from the correlated double sampler 1006, into digital signals, and then output the converted digital signals.

The input/output buffer 1008 may latch the digital signals and then sequentially output the latched digital signals to an image signal processing unit (not shown) in response to obtaining the decoded result from the column decoder 1004.

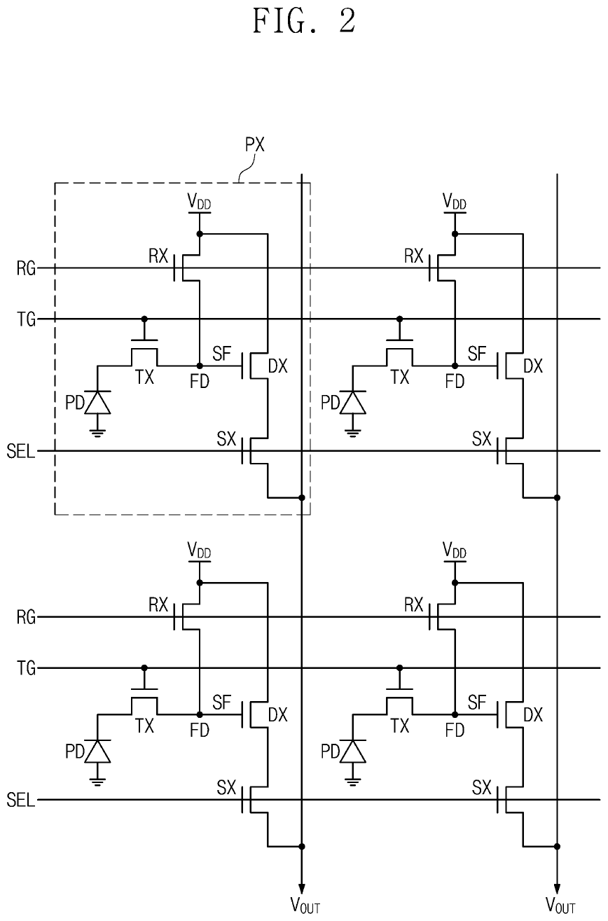

FIG. 2 illustrates a circuit diagram showing an active pixel sensor array of an image sensor according to some embodiments of the present disclosure.

Referring to FIGS. 1 and 2, the active pixel sensor array 1001 may include a plurality of pixel areas PX, and the pixel areas PX may be arranged in a matrix shape. Each pixel area PX may include a transfer transistor TX. Each pixel area PX may further include logic transistors RX, SX, and DX. The logic transistors RX, SX, and DX may include a reset transistor RX, a selection transistor SX, and a source follower transistor DX. The transfer transistor TX may include a transfer gate electrode TG. Each of the pixel areas PX may further include a photoelectric conversion element PD and a floating diffusion region FD. The logic transistors RX, SX, and DX may be shared by a plurality of pixel areas PX.

The photoelectric conversion element PD may create and accumulate photo-charges in proportion to an amount of externally incident light. The photoelectric conversion element PD may include a photodiode, phototransistor, a photogate, a pinned photodiode, or a combination thereof. The transfer transistor TX may transfer charges generated in the photoelectric conversion element PD into the floating diffusion region FD. The floating diffusion region FD may accumulate and store charges that are generated and transferred from the photoelectric conversion element PD. The source follower transistor DX may be controlled by an amount of photo-charges accumulated in the floating diffusion region FD.

The reset transistor RX may periodically reset the charges accumulated in the floating diffusion region FD. The reset transistor RX may have a drain electrode connected to the floating diffusion region FD and a source electrode connected to a power voltage V_{DD}. When the reset transistor RX is turned on, the floating diffusion region FD may be supplied with the power voltage V_{DD} connected to the source electrode of the reset transistor RX. Accordingly, when the reset transistor RX is turned on, the charges accumulated in the floating diffusion region FD may be exhausted and thus the floating diffusion region FD may be reset.

The source follower transistor DX including a source follower gate SF may serve as a source follower buffer amplifier. The source follower transistor DX may amplify a variation in electrical potential of the floating diffusion region FD and may output the amplified electrical potential to an output line V_{OUT}.

The selection transistor SX including a selection gate SEL may select each row of the pixel area PX to be read out. When the selection transistor SX is turned on, the power voltage V_{DD} may be applied to a drain electrode of the source follower transistor DX.

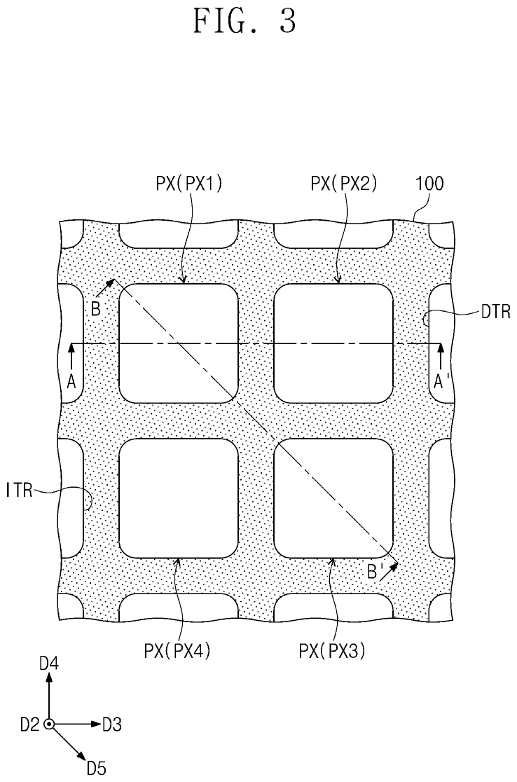

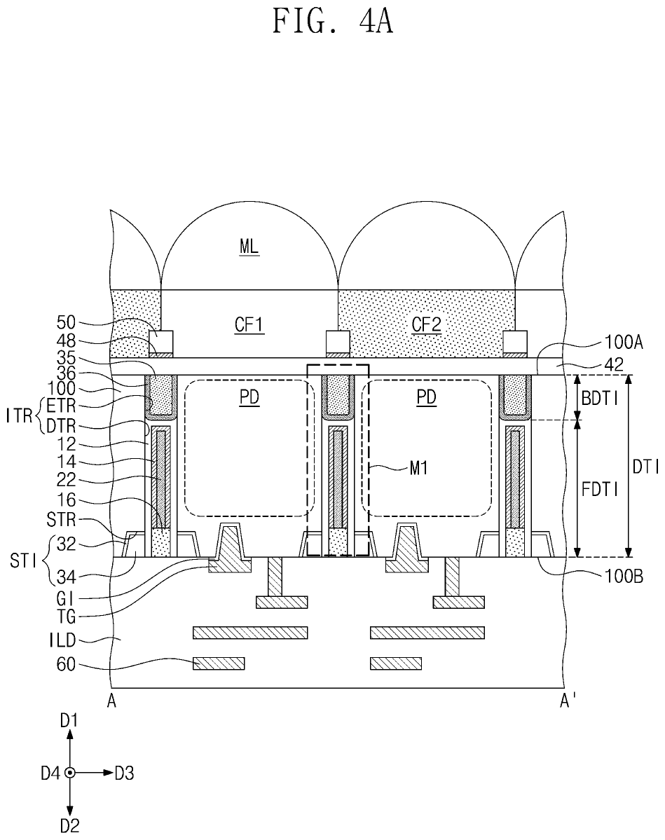

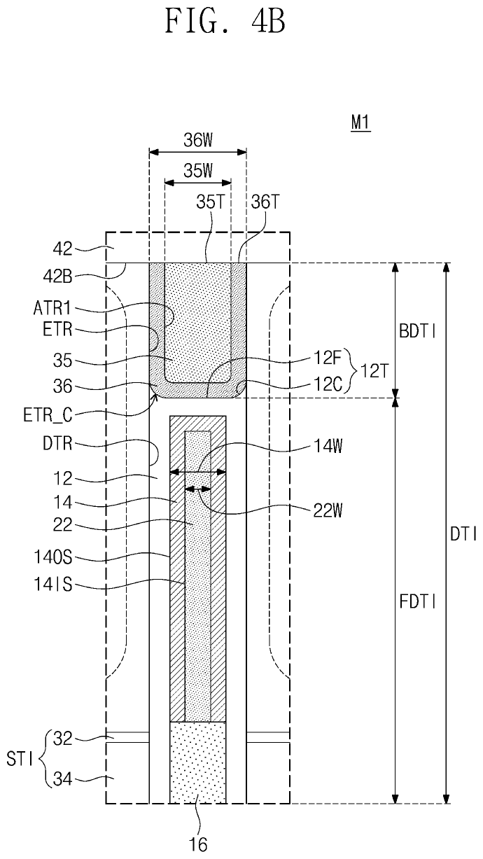

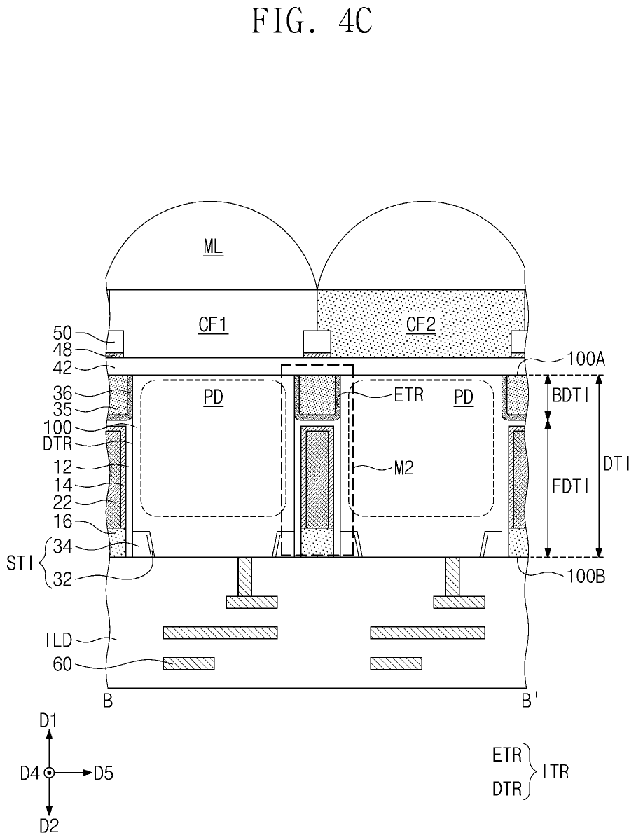

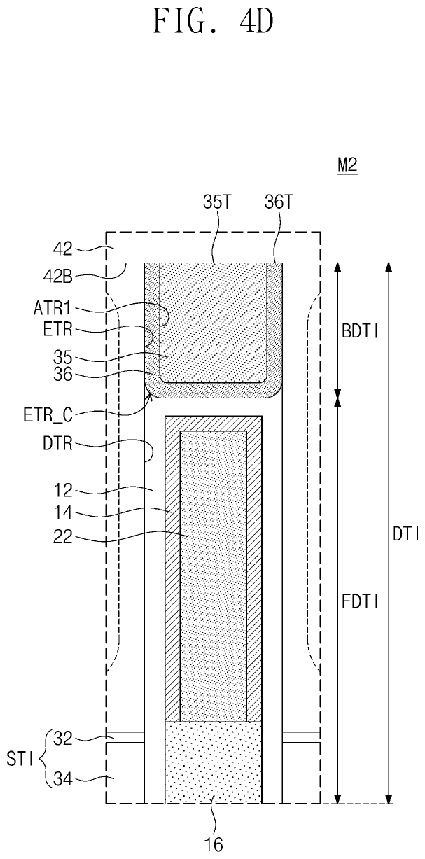

FIG. 3 illustrates a plan view showing an image sensor according to some embodiments of the present disclosure. FIG. 4A illustrates a cross-sectional view taken along line A-A′ of FIG. 3. FIG. 4B illustrates an enlarged view showing section M1 of FIG. 4A. FIG. 4C illustrates a cross-sectional view taken along line B-B′ of FIG. 3. FIG. 4D illustrates an enlarged view showing section M2 of FIG. 4C.

Referring to FIGS. 3 and 4A to 4D, a substrate 100 may be provided. For example, the substrate 100 may be a monocrystalline silicon wafer, a silicon epitaxial layer, or a silicon-on-insulator (SOI) substrate. The substrate 100 may be doped with impurities to have a first conductivity type (e.g., p-type). The substrate 100 may have a first surface 100A and a second surface 100B that are opposite to each other. The first surface 100A may be spaced apart from the second surface 100B in a first direction D1, and the second surface 100B may be spaced apart from the first surface 100A in a second direction D2. The first direction D1 and the second direction D2 may be opposite to each other.

The substrate 100 may include a plurality of pixel areas PX. For example, when viewed in plan, the substrate 100 may include first, second, third, and fourth pixel areas PX1, PX2, PX3, and PX4 that are sequentially arranged in a clockwise direction. The first and second pixel areas PX1 and PX2 may be adjacent to each other in a third direction D3, and the third and fourth pixel areas PX3 and PX4 may be adjacent to each other in the third direction D3. The third direction D3 may be parallel to the second surface 100B of the substrate 100. The second and third pixel areas PX2 and PX3 may be adjacent to each other in a fourth direction D4, and the first and fourth pixel areas PX1 and PX4 may be adjacent to each other in the fourth direction D4. The fourth direction D4 may be parallel to the second surface 100B of the substrate 100, and may intersect the third direction D3.

An isolation pattern DTI may be in the substrate 100. The isolation pattern DTI may separate the pixel areas PX from each other. The isolation pattern DTI may penetrate or extend in the second direction D2 and through the substrate 100 between the pixel areas PX.

The isolation pattern DTI may be disposed in an isolation trench ITR that extends from the first surface 100A toward the second surface 100B. The isolation trench ITR may include a deep trench DTR and an extension trench ETR. When viewed in plan, the isolation pattern DTI may have a network shape in which lines extending in the third and fourth directions D3 and D4 intersect each other.

The isolation pattern DTI may extend from the second surface 100B into the substrate 100, and may be interposed between a plurality of pixel areas PX. The isolation pattern DTI may include a first device isolation pattern BDTI and a second device isolation pattern FDTI. The first device isolation pattern BDTI may be adjacent to the first surface 100A of the substrate 100, and the second device isolation pattern FDTI may be adjacent to the second surface 100B of the substrate 100. The first device isolation pattern BDTI may be provided in the extension trench ETR. The second device isolation pattern FDTI may be provided in the deep trench DTR.

In an embodiment, a distance in the second direction D2 of the first device isolation pattern BDTI may be less than a distance in the second direction D2 of the second device isolation pattern FDTI. The first device isolation pattern BDTI may be disposed on the second device isolation pattern FDTI.

The first device isolation pattern BDTI may include a first dielectric layer 36 and a conductive reflection layer 35 on the first dielectric layer 36.

The extension trench ETR may have a curved portion ETR_C. The curved portion ETR_C may be formed at a location where the first device isolation pattern BDTI and the second device isolation pattern FDTI are in contact with each other. The curved portion ETR_C may be disposed between the first device isolation pattern BDTI and the second device isolation pattern FDTI.

The first dielectric layer 36 may be formed to conformally cover or overlap the extension trench ETR. The first dielectric layer 36 may form a first additional trench ATR1.

The first dielectric layer 36 may include a dielectric material. The first dielectric layer 36 may include an oxide. The first dielectric layer 36 may include, for example, Al₂O₃, HfO, SiO2, and/or pentyltriethoxysiloxane (PTEOS). The conductive reflection layer 35 may include a conductive material. The conductive reflection layer 35 may include, for example, Cu, Al, W, Ti, and/or Ag.

The conductive reflection layer 35 may be buried in the first dielectric layer 36. The conductive reflection layer 35 may be in the first additional trench ATR1. The conductive reflection layer 35 may have a top surface 35T at the same level as that of a top surface 36T of the first dielectric layer 36 (e.g., the top surface 35T of the conductive reflection layer 35 and the top surface 36T of the first dielectric layer 36 extend from the second surface 100B of the substrate 100 by a same distance in the first direction D1). The first dielectric layer 36 may have a width 36W greater than a width 35W of the conductive reflection layer 35.

An antireflection layer 42 may be disposed on the first device isolation pattern BDTI. The antireflection layer 42 may be provided on and cover/overlap the first surface 100A of the substrate 100. The antireflection layer 42 may have a bottom surface 42B in contact with the first surface 100A of the substrate 100, the top surface 36T of the first dielectric layer 36, and the top surface 35T of the conductive reflection layer 35. The top surface 35T of the conductive reflection layer 35 may be coplanar with the top surface 36T of the first dielectric layer 36 and the bottom surface 42B of the antireflection layer 42.

The antireflection layer 42 may include an oxide. The antireflection layer 42 may include, for example, Al₂O₃, HfO, SiO₂, and/or pentyltriethoxysiloxane (PTEOS). The antireflection layer 42 may include the same material as that of the first dielectric layer 36.

The second device isolation pattern FDTI may be disposed below the first device isolation pattern BDTI. The second device isolation pattern FDTI may include a buried layer 22, a conductive liner 14 on the buried layer 22, a dielectric liner 12 on the conductive liner 14, and a buried dielectric pattern 16.

The buried layer 22 may have a lateral surface and a top surface that are at least partially surrounded by the conductive liner 14. The conductive liner 14 may have an inner sidewall 14IS in contact with the buried layer 22. The conductive liner 14 may have an outer sidewall OS in contact with the dielectric liner 12.

The conductive liner 14 may have a width 14W greater than a width 22W of the buried layer 22. The width 14W of the conductive liner 14 may be less than the width 36W of the first dielectric layer 36.

The dielectric liner 12 may at least partially surround a top surface of the conductive liner 14 and the outer sidewall OS of the conductive liner 14.

The buried layer 22 may include polysilicon or oxide. The buried layer 22 may include, for example, boron-doped silicon or undoped silicon. For example, the buried layer 22 may include SiO₂.

The conductive liner 14 may include silicon. For example, the conductive liner 14 may include boron-doped silicon.

The dielectric liner 12 may include an oxide or a nitride. For example, the dielectric liner 12 may include SiO₂ or Si₃N₄. The dielectric liner 12 and the first dielectric layer 36 may include different materials. The dielectric liner 12 and the first dielectric layer 36 may have different lattice constants. An interface may be present between the dielectric liner 12 and the first dielectric layer 36.

The dielectric liner 12 may have a top surface 12T that includes a curved surface 12C and a flat surface 12F that is parallel to the first surface 100A of the substrate 100. The curved surface 12C may be disposed between the flat surface 12F and a lateral surface of the dielectric liner 12.

The buried dielectric pattern 16 may penetrate or extend through a shallow device isolation section STI. The dielectric liner 12 may be interposed between the buried dielectric pattern 16 and the shallow device isolation section STI.

A photoelectric conversion element PD may be provided in each of the pixel areas PX. The photoelectric conversion element PD may be doped with impurities having a second conductivity type (e.g., n-type) opposite to the first conductivity type. The impurities doped into the photoelectric conversion element PD and the impurities having the first conductivity type in the substrate 100 may constitute a PN junction, thereby providing a photodiode.

A shallow device isolation trench STR may be=recessed into the substrate 100 from the second surface 100B of the substrate 100, and the shallow device isolation section STI may be in the shallow device isolation trench STR. The shallow device isolation section STI may be disposed adjacent to the second surface 100B of the substrate 100.

The shallow device isolation section STI may include a first isolation portion 32 and a second isolation portion 34. The first isolation portion 32 may conformally cover or overlap an inner wall of the shallow device isolation trench STR. The second isolation portion 34 may be in the shallow device isolation trench STR. The first and second isolation portions 32 and 34 may independently include at least one selected from silicon oxide (SiO), silicon nitride (SiN), silicon carbonitride (SiCN), silicon oxycarbonitride (SiOCN), and a combination thereof. The isolation pattern DTI may extend in the second direction D2 and through the shallow device isolation section STI. On the pixel area PX, the shallow device isolation section STI may limit active regions adjacent to the second surface 100B of the substrate 100. The active regions may be provided for the transistors TX, RX, DX, and SX of FIG. 2.

On each pixel area PX, a transfer gate TG may be provided on the first surface 100A of the substrate 100. For example, a portion of the transfer gate TG may be buried in the substrate 100. The transfer gate TG may be a vertical type. Alternatively, the transfer gate TG may be a planar type that is flat on the first surface 100A of the substrate 100.

A gate dielectric pattern GI may be interposed between the transfer gate TG and the substrate 100. A floating diffusion region (not shown) may be provided in the substrate 100, while being adjacent to one side of the transfer gate TG. For example, the floating diffusion region (not shown) may be implanted with impurities having the second conductivity type.

According to some embodiments of the present disclosure, light may pass through the first surface 100A of the substrate 100 to enter the substrate 100. Electron-hole pairs may be created from the incident light at the PN junction. These created electrons may move toward the photoelectric conversion element PD. When a voltage is applied to the transfer gate TG, the electrons may move to the floating diffusion region (not shown).

An interlayer dielectric layer ILD may be provided on and cover/overlap the second surface 100B of the substrate 100. The interlayer dielectric layer ILD may be a multiple layer structure including at least one selected from a silicon oxide layer, a silicon nitride layer, a silicon oxynitride layer, a porous low-k dielectric layer, and a combination thereof. The interlayer dielectric layer ILD may be provided with wiring lines 60 therein. The floating diffusion region (not shown) may be connected to the wiring lines 60.

Light-shield patterns 48 may be disposed on the antireflection layer 42. Low-refractive patterns 50 may be correspondingly disposed on the light-shield patterns 48. The light-shield pattern 48 and the low-refractive pattern 50 may overlap the isolation pattern DTI and may have a grid shape when viewed in plan. The light-shield pattern 48 may include, for example, titanium. The low-refractive pattern 50 may have the same thickness as the light-shield pattern 48 in the third direction D3 and include an organic material. The low-refractive pattern 50 may have a refractive index less than that of color filters CF1 and CF2, which will be discussed below. The light-shield pattern 48 and the low-refractive pattern 50 may prevent crosstalk between neighboring pixel areas PX.

Color filters CF1 and CF2 may be disposed between the low-refractive patterns 50. The color filters CF1 and CF2 may each have one of blue, green, and red colors. Alternatively, the color filters CF1 and CF2 may have different colors, such as cyan, magenta, or yellow. In an image sensor according to the present embodiment, the color filters CF1 and CF2 may be arranged as a Bayer pattern. Alternatively, the color filters CF1 and CF2 may be arranged as one of a 2×2 Tetra pattern, a 3×3 Nona pattern, and a 4×4 Hexadeca pattern.

Microlenses ML may be disposed on the color filters CF1 and CF2. The microlenses ML may have edges in contact with and connected to each other.

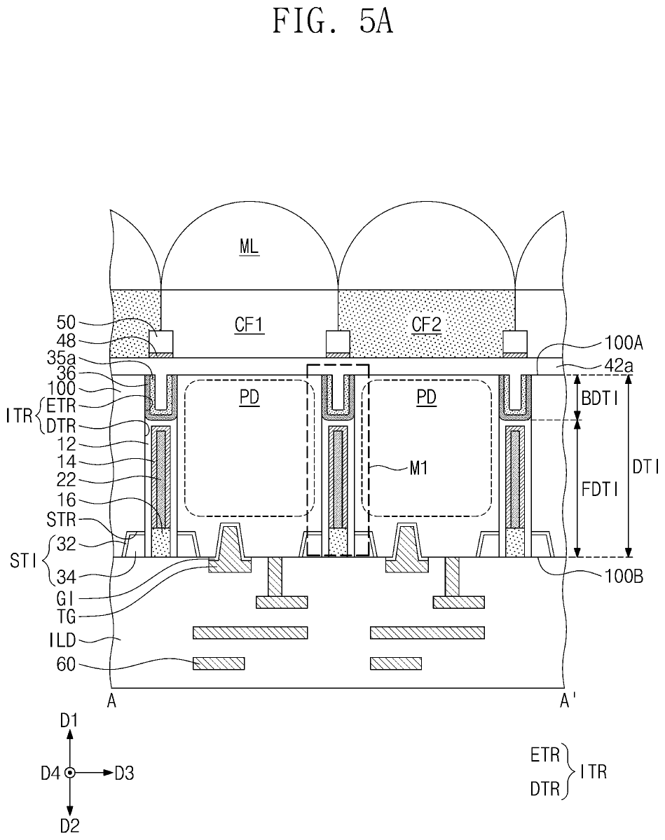

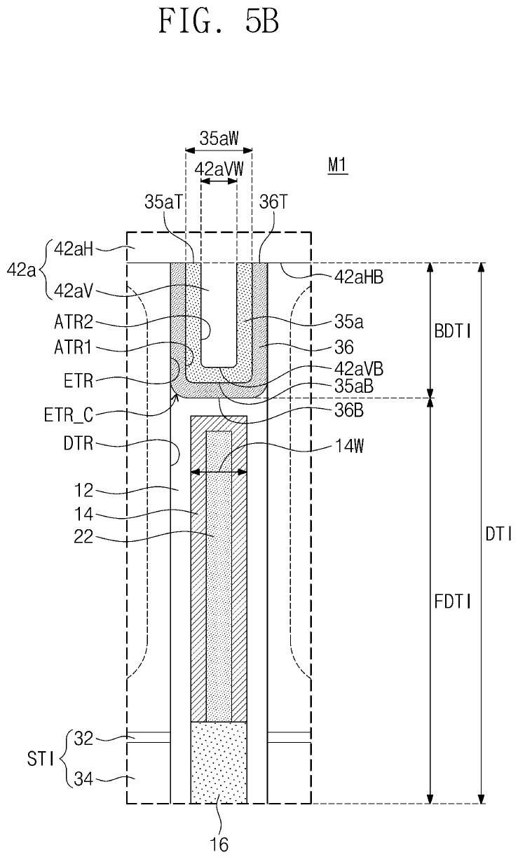

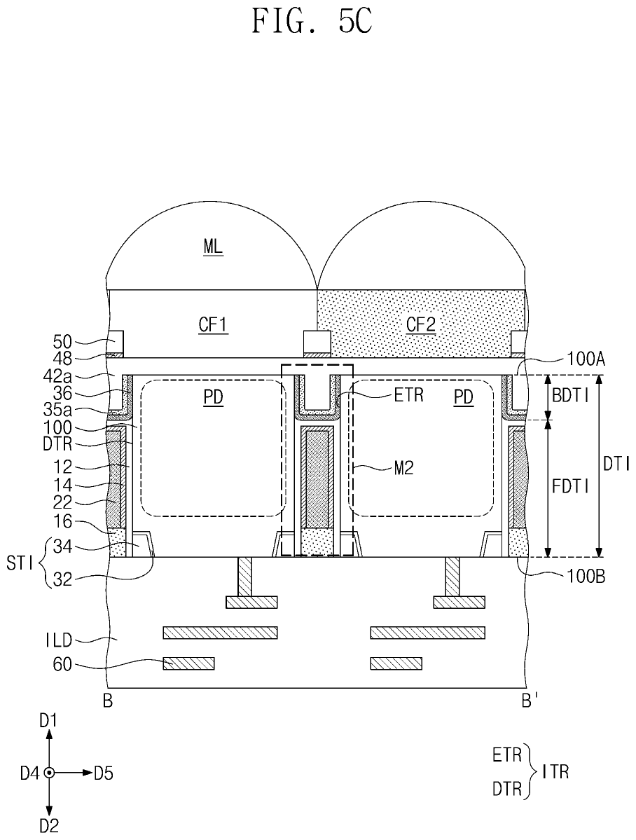

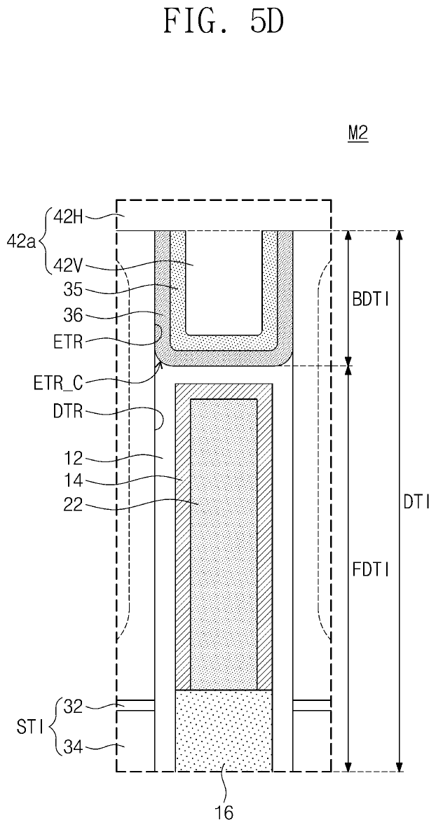

FIG. 5A illustrates a cross-sectional view taken along line A-A′ of FIG. 3, showing an image sensor according to some embodiments of the present disclosure. FIG. 5B illustrates an enlarged view showing section M1 of FIG. 5A. FIG. 5C illustrates a cross-sectional view taken along line B-B′ of FIG. 3, showing an image sensor according to some embodiments of the present disclosure. FIG. 5D illustrates an enlarged view showing section M2 of FIG. 5C. For brevity of description, a repetitive description will be omitted.

Referring to FIGS. 3 and 5A to 5D, the isolation pattern DTI may be positioned in the substrate 100. The isolation pattern DTI may include a first device isolation pattern BDTI and a second device isolation pattern FDTI. The first device isolation pattern BDTI may be adjacent to the first surface 100A of the substrate 100, and the second device isolation pattern FDTI may be adjacent to the second surface 100B of the substrate 100. The first device isolation pattern BDTI may be provided in the extension trench ETR. The second device isolation pattern FDTI may be provided in the deep trench DTR.

The first device isolation pattern BDTI may include a first dielectric layer 36 and a conductive reflection layer 35a on the first dielectric layer 36.

The extension trench ETR may have a curved portion ETR_C. The curved portion ETR_C may be formed at a location where the first device isolation pattern BDTI and the second device isolation pattern FDTI are in contact with each other. The curved portion ETR_C may be disposed between the first device isolation pattern BDTI and the second device isolation pattern FDTI.

The first dielectric layer 36 may be formed to conformally cover or overlap the extension trench ETR. The first dielectric layer 36 may form a first additional trench ATR1.

The conductive reflection layer 35a may be formed to conformally cover or overlap the first additional trench ATR1. The conductive reflection layer 35a may form a second additional trench ATR2. The second additional trench ATR2 may include a vertical layer portion 42aV of an antireflection layer 42a therein, which will be discussed below.

An antireflection layer 42a may be disposed on the first device isolation pattern BDTI. The antireflection layer 42a may include a parallel layer portion 42aH and a vertical layer portion 42aV. The parallel layer portion 42aH may extend in a direction parallel to the first surface 100A of the substrate 100. The vertical layer portion 42aV may be in contact with the conductive reflection layer 35a, while extending from the first surface 100A toward the second surface 100B of the substrate 100. The vertical layer portion 42aV may be in the second additional trench ATR2. The vertical layer portion 42aV may have a lateral surface and a bottom surface 42aVB that are in contact with the conductive reflection layer 35a. The lateral surface and the bottom surface 42aVB of the vertical layer portion 42aV may be at least partially surrounded by the conductive reflection layer 35a.

The conductive reflection layer 35a may have a top surface 35aT at the same level as that of a bottom surface 42aHB of the parallel layer portion 42aH (e.g., the top surface 35aT and the bottom surface 42aHB extend from the second surface 100B of the substrate 100 by a same distance in the first direction D1). The first dielectric layer 36 may have a top surface 36T at the same level as that of the bottom surface 42aHB of the parallel layer portion 42aH (e.g., the top surface 36T and the bottom surface 42aHB extend from the second surface 100B of the substrate 100 by a same distance in the first direction D1). The bottom surface 42aHB of the parallel layer portion 42aH may be in contact with the top surface 36T of the first dielectric layer 36. The bottom surface 42aHB of the parallel layer portion 42aH may be in contact with the top surface 35aT of the conductive reflection layer 35a.

The vertical layer portion 42aV may have a bottom surface 42aVB at a level higher than that of a bottom surface 35aB of the conductive reflection layer 35a (e.g., the bottom surface 42aVB extends from the second surface 100B of the substrate 100 by a greater distance in the first direction D1 than the bottom surface 35aB extends from the second surface 100B of the substrate 100). The level of the bottom surface 42aVB of the vertical layer portion 42aV may be higher than that of a bottom surface 36B of the first dielectric layer 36 (e.g., the bottom surface 42aVB extends from the second surface 100B of the substrate 100 by a greater distance in the first direction D1 than the bottom surface 36B extends from the second surface 100B of the substrate 100). The level of the bottom surface 35aB of the conductive reflection layer 35a may be higher than that of the bottom surface 36B of the first dielectric layer 36 (e.g., the bottom surface 35aB extends from the second surface 100B of the substrate 100 by a greater distance in the first direction D1 than the bottom surface 36B extends from the second surface 100B of the substrate 100).

The second device isolation pattern FDTI may be disposed below the first device isolation pattern BDTI. The second device isolation pattern FDTI may include a buried layer 22, a conductive liner 14 on the buried layer 22, and a dielectric liner 12 on the conductive liner 14.

The vertical layer portion 42aV may have a width 42aVW that may be less than a width 14W of the conductive liner 14. The width 42aVW of the vertical layer portion 42aV may be less than a width 35aW of the conductive reflection layer 35a.

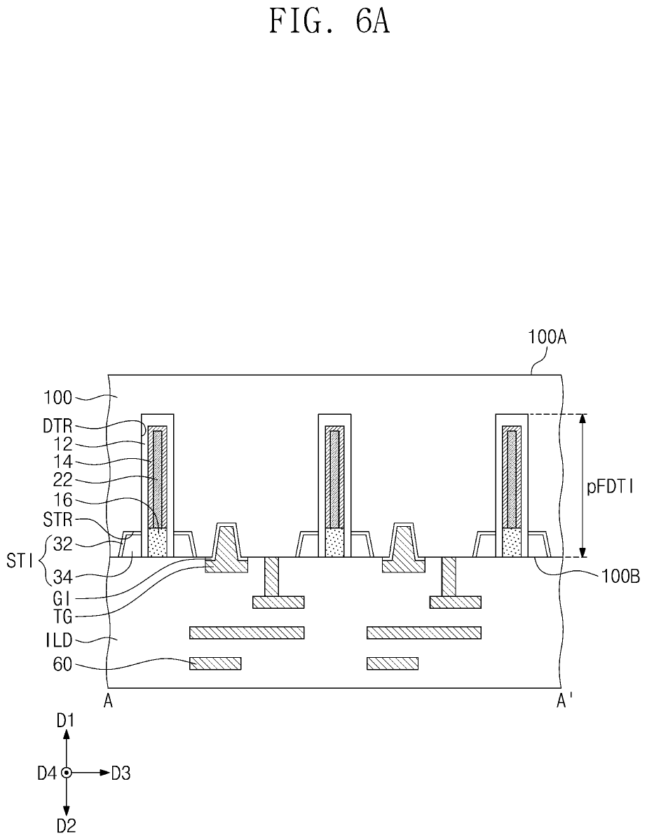

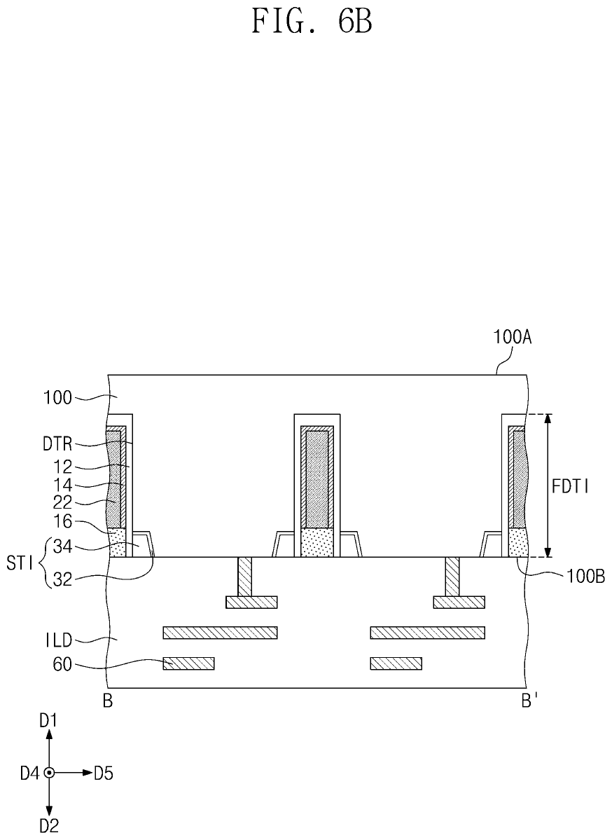

FIGS. 6A to 11B illustrate cross-sectional views taken along lines A-A′ and B-B′ of FIG. 3, showing a method of fabricating an image sensor according to some embodiments of the present disclosure.

Referring to FIGS. 6A and 6B, a substrate 100 may be prepared. A wiring process, a trimming process, and a bonding process may be used to provide an interlayer dielectric layer ILD, wiring lines 60 in the interlayer dielectric layer ILD, a gate dielectric pattern GI, a transfer gate TG, and a substrate 100 on the interlayer dielectric layer ILD.

The substrate 100 may be provided and includes therein a shallow device isolation section STI and a preliminary second device isolation pattern pFDTI. The preliminary second device isolation pattern pFDTI may be provided in a deep trench DTR, and may include a buried dielectric pattern 16, a buried layer 22 on the buried dielectric pattern 16, a conductive liner 14 on the buried layer 22, and a dielectric liner 12 on the conductive liner 14. A top surface of the dielectric liner 12 may be flat.

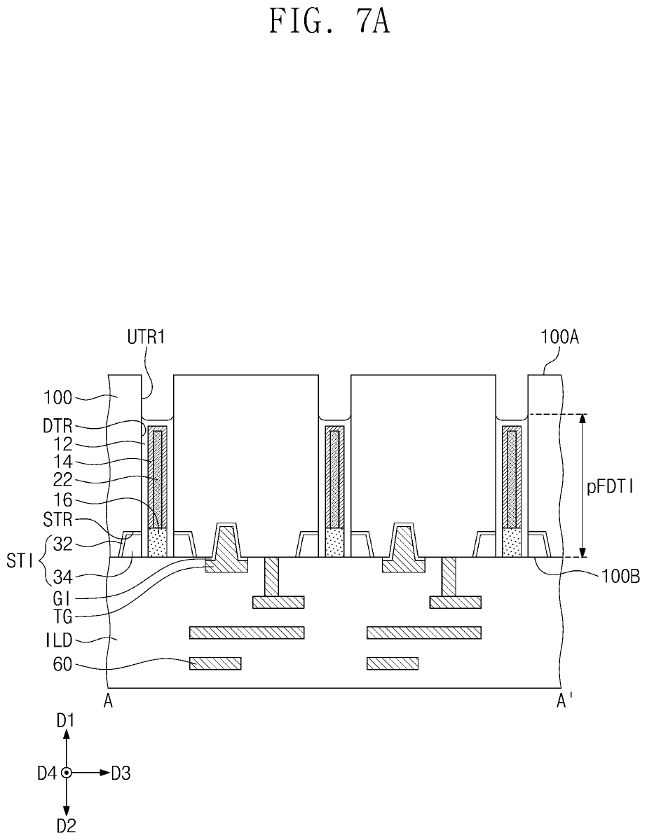

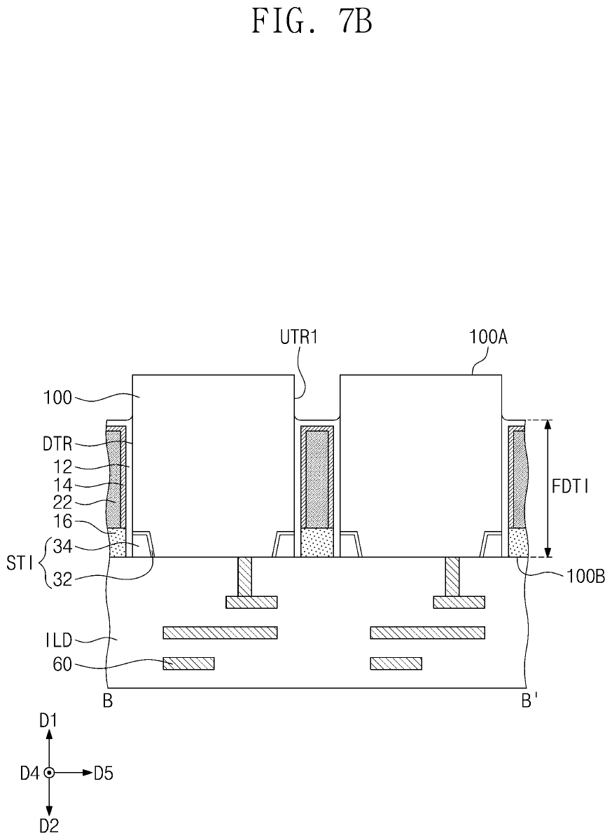

Referring to FIGS. 7A and 7B, a first upper trench UTR1 may be formed. The formation of the first upper trench UTR1 may include forming a mask on a first surface 100A of the substrate 100 and using the mask pattern as an etching mask to etch the substrate 100. A portion of the mask pattern may remain (or may not remain) after the etching process. A bottom surface of the first upper trench UTR1 may include a curved surface.

During the formation of the first upper trench UTR1, the top surface of the dielectric liner 12 may be partially etched. The top surface of the dielectric liner 12 may be exposed. The exposed top surface of the dielectric liner 12 may include a curved surface. A second device isolation pattern FDTI may be defined to indicate the preliminary second device isolation pattern pFDTI whose dielectric liner 12 is etched.

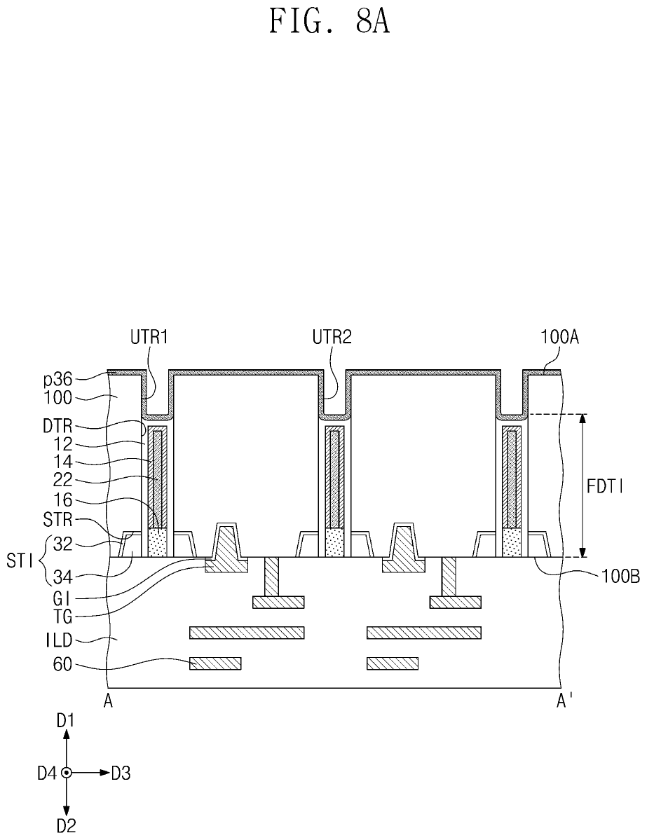

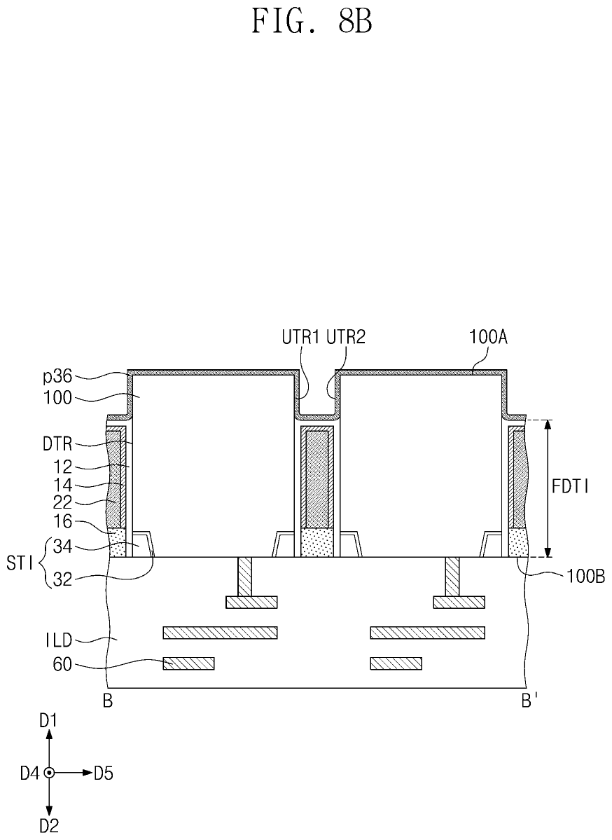

Referring to FIGS. 8A and 8B, a preliminary first dielectric layer p36 may be formed to cover or overlap an inner wall of the first upper trench UTR1 and the first surface 100A of the substrate 100. The preliminary first dielectric layer p36 may conformally cover or overlap the inner wall of the first upper trench UTR1 and the first surface 100A of the substrate 100. Therefore, the preliminary first dielectric layer p36 may form a second upper trench UTR2.

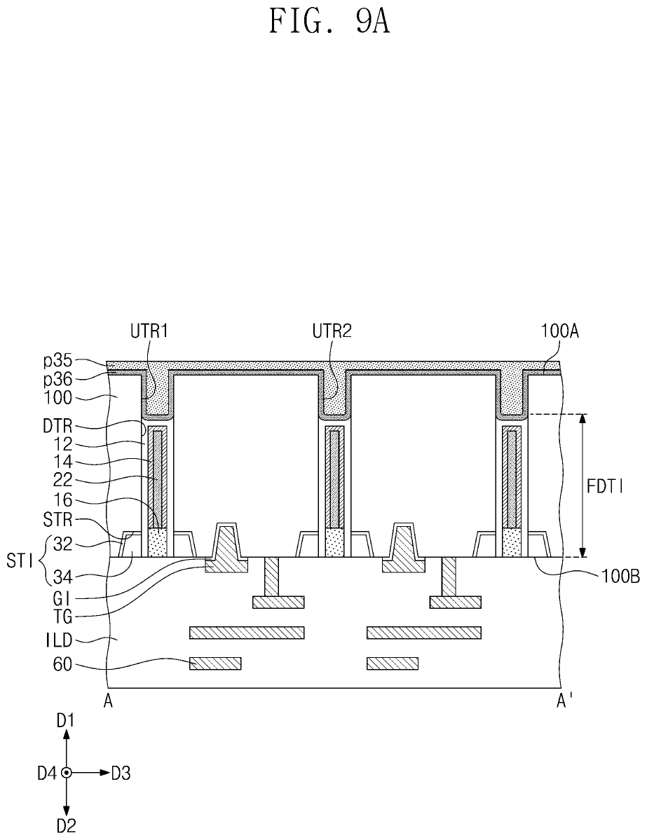

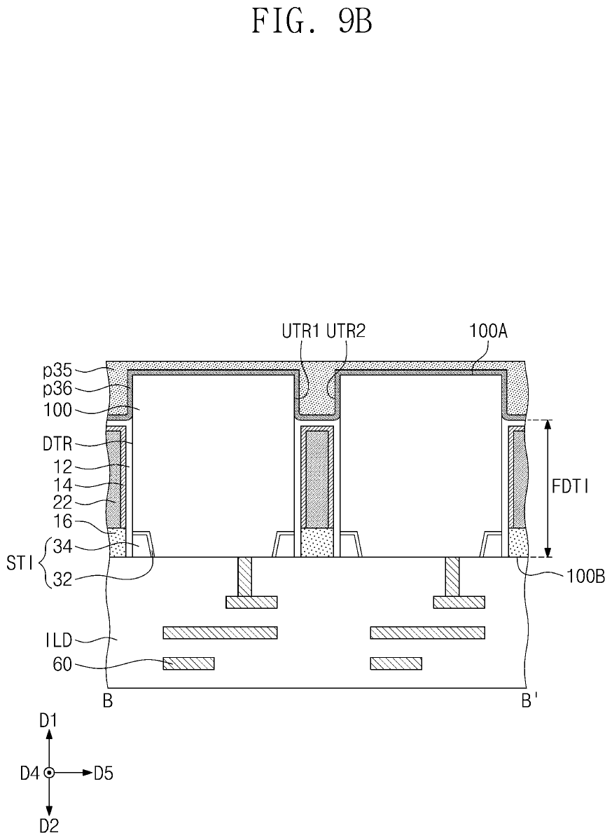

Referring to FIGS. 9A and 9B, a preliminary conductive reflection layer p35 may be formed on the preliminary first dielectric layer p36. The preliminary conductive reflection layer p35 may be formed to be in the second upper trench UTR2 and to cover or overlap a top surface of the preliminary first dielectric layer p36.

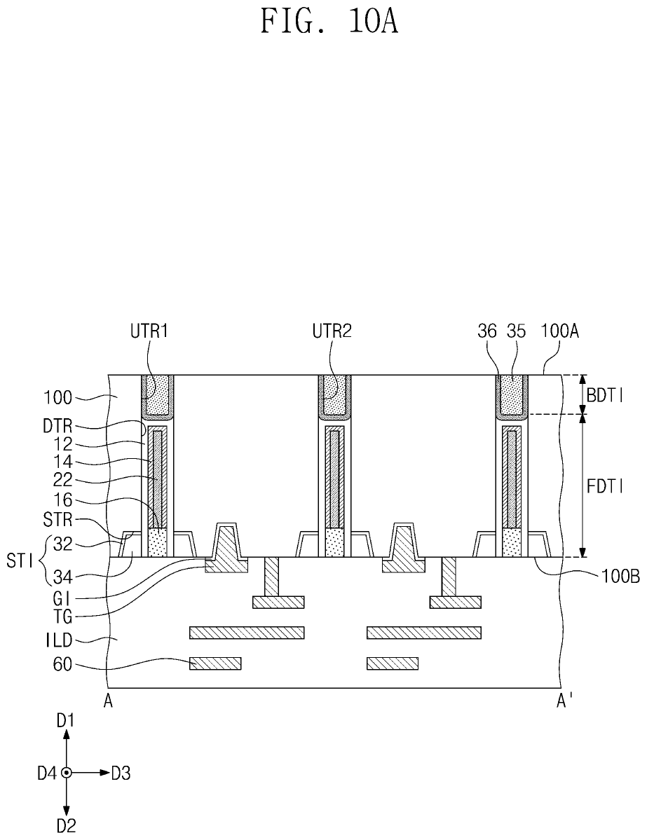

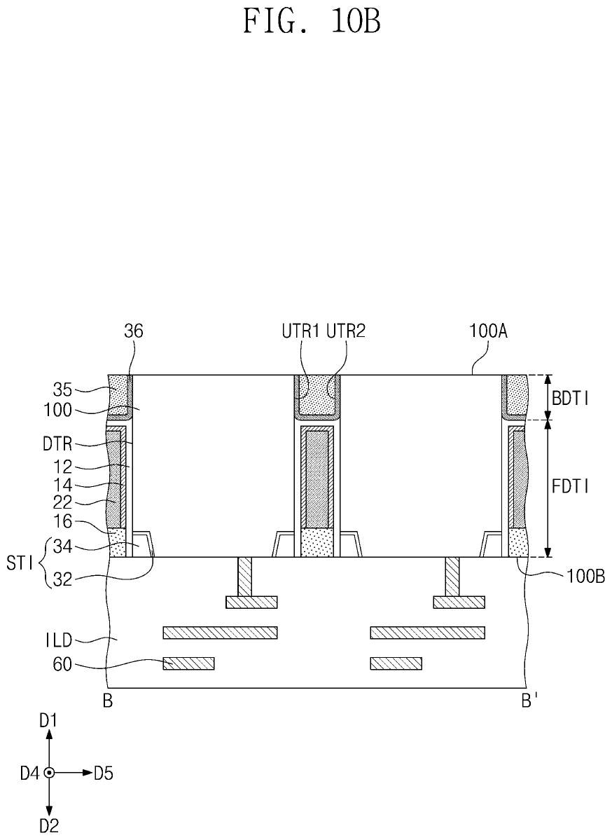

Referring to FIGS. 10A and 10B, an upper portion of the preliminary conductive reflection layer p35 may be removed, and likewise an upper portion of the preliminary first dielectric layer p36 may be removed. The preliminary conductive reflection layer p35 and the preliminary first dielectric layer p36 may be removed to expose the first surface 100A of the substrate 100. The removal of the upper portion of the preliminary conductive reflection layer p35 and the upper portion of the preliminary first dielectric layer p36 may include, for example, removing the preliminary first dielectric layer p36 and the preliminary conductive reflection layer p35 to allow the preliminary first dielectric layer p36 to remain in the first upper trench UTR1 and to allow the preliminary conductive reflection layer p35 to remain in the second upper trench UTR2. The removal of the upper portion of the preliminary conductive reflection layer p35 and the upper portion of the preliminary first dielectric layer p36 may include performing an etch-back process on the preliminary conductive reflection layer p35 and the preliminary first dielectric layer p36.

The upper portion of the preliminary first dielectric layer p36 may be removed to form first dielectric layers 36. The preliminary first dielectric layer p36 may be divided into the first dielectric layers 36. The upper portion of the preliminary conductive reflection layer p35 may be removed to form conductive reflection layers 35. The preliminary conductive reflection layer p35 may be divided into the conductive reflection layers 35. Therefore, a first device isolation pattern BDTI may be formed, which includes the conductive reflection layer 35 and the first dielectric layer 36.

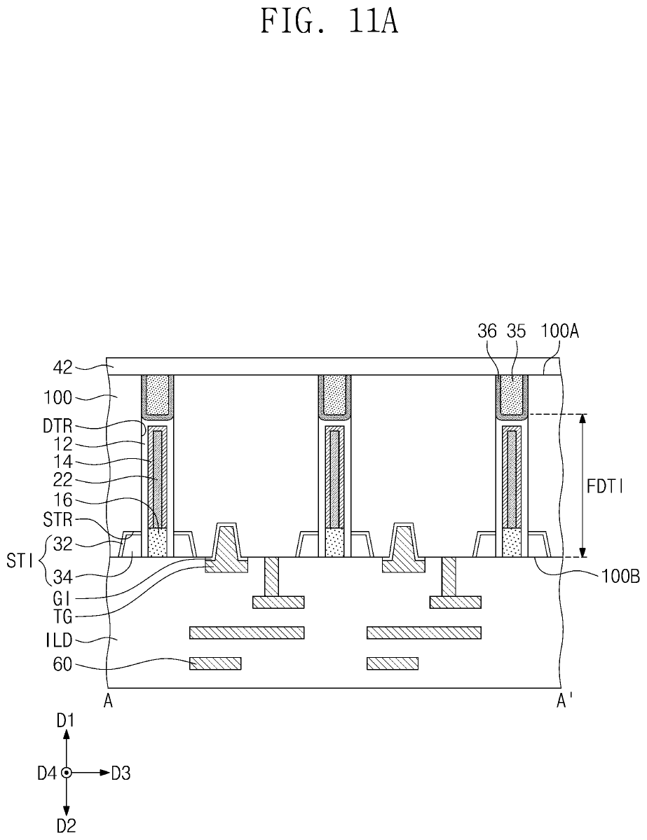

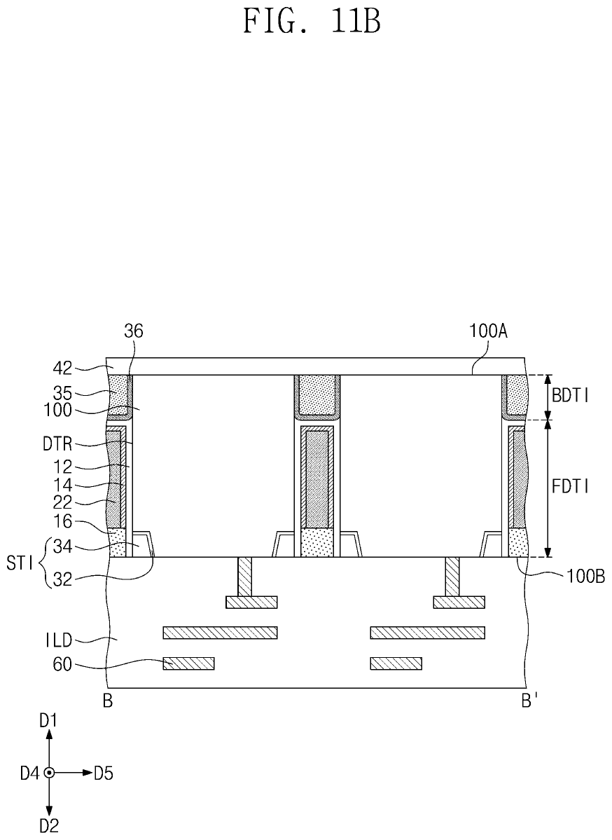

Referring to FIGS. 11A and 11B, an antireflection layer 42 may be formed on the first surface 100A of the substrate 100, the conductive reflection layer 35, and the first dielectric layer 36.

Afterwards, light-shield patterns 48 may be formed on the antireflection layer 42, and low-refractive patterns 50 may be formed on the light-shield patterns 48. Color filters CF1 and CF2 may be formed between the low-refractive patterns 50. Microlenses ML may be formed on the color filters CF1 and CF2, and thus an image sensor may be fabricated as shown in FIGS. 3 to 4D.

According to the present disclosure, an image sensor may be configured such that a conductive reflection layer may be included on a dielectric layer of a first device isolation pattern, and therefore the conductive reflection layer may increase the light reflection efficiency and improve the sensitivity of the image sensor.

According to the present disclosure, a conductive reflection layer may be included on a dielectric layer of a first device isolation pattern, a second device isolation pattern may include a buried layer and a conductive liner, a contact for negative bias may be connected to the conductive reflection layer of the first device isolation pattern and to the buried layer and the conductive liner of the second device isolation pattern, and a negative bias may be applied.

The aforementioned description provides some embodiments for explaining the present disclosure. Therefore, the present disclosure are not limited to the embodiments described above, and it will be understood by one of ordinary skill in the art that variations in form and detail may be made therein without departing from the spirit and essential features of the present disclosure.

What is claimed is:

1. An image sensor, comprising:
a substrate that comprises a first surface and a second surface that are opposite to each other, wherein the substrate comprises a plurality of pixel areas;
an isolation pattern that extends from the first surface and into the substrate, wherein the isolation pattern is between the plurality of pixel areas; and
an antireflection layer on the isolation pattern,
wherein the isolation pattern comprises:
a first device isolation pattern that contacts the antireflection layer; and
a second device isolation pattern that is spaced apart from the antireflection layer,
wherein the first device isolation pattern comprises:
a first dielectric layer; and
a conductive reflection layer on the first dielectric layer, and
wherein a top surface of the conductive reflection layer and a top surface of the first dielectric layer extend from the second surface of the substrate by a same distance.

2. The image sensor of claim 1, wherein:
the first device isolation pattern is in an extension trench,
the extension trench comprises a curved portion, and
the curved portion is between the first device isolation pattern and the second device isolation pattern.

3. The image sensor of claim 1, wherein the second device isolation pattern comprises:
a buried layer;
a conductive liner on the buried layer; and
a dielectric liner on the conductive liner.

4. The image sensor of claim 3, wherein a lattice constant of the first dielectric layer is different from a lattice constant of the dielectric liner.

5. The image sensor of claim 3, wherein a top surface of the dielectric liner comprises a curved surface.

6. The image sensor of claim 3, wherein the dielectric liner and the first dielectric layer comprise different materials.

7. The image sensor of claim 1, wherein the conductive reflection layer comprises at least one of Cu, Al, W, Ti, and Ag.

8. The image sensor of claim 1, wherein:
the antireflection layer comprises a parallel layer portion and a vertical layer portion,
the top surface of the conductive reflection layer contacts a bottom surface of the parallel layer portion, and
the vertical layer portion is at least partially surrounded by the conductive reflection layer.

9. The image sensor of claim 8, wherein a bottom surface of the vertical layer portion extends from the second surface of the substrate by a first distance, a bottom surface of the conductive reflection layer extends from the second surface of the substrate by a second distance, and the first distance is greater than the second distance.

10. An image sensor, comprising:
a substrate that comprises a first surface and a second surface that are opposite to each other, wherein the substrate comprises a plurality of pixel areas;
an isolation pattern that extends from the first surface and into the substrate, wherein the isolation pattern is between the plurality of pixel areas; and
an antireflection layer on the isolation pattern,
wherein the isolation pattern comprises:
a first device isolation pattern that contacts the antireflection layer; and
a second device isolation pattern that is spaced apart from the antireflection layer,
wherein the first device isolation pattern comprises:
a first dielectric layer; and
a conductive reflection layer on the first dielectric layer, and
wherein the antireflection layer includes:
a parallel layer portion that extends in a direction that is parallel to the first surface of the substrate; and
a vertical layer portion that extends from the parallel layer portion toward the second surface of the substrate and contacts the conductive reflection layer.

11. The image sensor of claim 10, wherein a bottom surface of the vertical layer portion extends from the second surface of the substrate by a first distance, a bottom surface of the first dielectric layer extends from the second surface of the substrate by a second distance, and the first distance is greater than the second distance.

12. The image sensor of claim 10, wherein a bottom surface of the parallel layer portion contacts a top surface of the first dielectric layer and a top surface of the conductive reflection layer.

13. The image sensor of claim 10, wherein the second device isolation pattern comprises:
a buried layer;
a conductive liner on the buried layer; and
a dielectric liner on the conductive liner.

14. The image sensor of claim 13, wherein a width of the conductive liner is greater than a width of the vertical layer portion.

15. The image sensor of claim 13, wherein:
the buried layer comprises polysilicon or SiO₂, and
the conductive liner comprises boron-doped silicon.

16. The image sensor of claim 13, wherein the conductive reflection layer comprises at least one of Cu, Al, W, Ti, and Ag.

17. The image sensor of claim 13, wherein a top surface of the dielectric liner comprises a curved surface and a flat surface that is parallel to the first surface of the substrate.

18. The image sensor of claim 10, wherein a lateral surface and a bottom surface of the vertical layer portion are at least partially surrounded by the conductive reflection layer.

19. An image sensor, comprising:
a substrate that comprises a first surface and a second surface that are opposite to each other, wherein the substrate comprises a plurality of pixel areas;
a plurality of microlenses on the first surface of the substrate;
a transfer gate on the second surface of the substrate;
an isolation pattern that extends from the first surface and into the substrate, wherein the isolation pattern is between the plurality of pixel areas; and
an antireflection layer on the isolation pattern,
wherein the isolation pattern comprises:
a first device isolation pattern that contacts the antireflection layer; and
a second device isolation pattern that is spaced apart from the antireflection layer,
wherein the first device isolation pattern comprises:
a first dielectric layer; and
a conductive reflection layer on the first dielectric layer,
wherein the second device isolation pattern comprises:
a buried layer;
a conductive liner on the buried layer; and
a dielectric liner on the conductive liner, and
wherein the antireflection layer includes:
a parallel layer portion that is parallel to the first surface of the substrate; and
a vertical layer portion that extends from the parallel layer portion and toward the second surface of the substrate, wherein the vertical layer portion contacts the conductive reflection layer.

20. The image sensor of claim 19, wherein:
a bottom surface of the first dielectric layer contacts a top surface of the dielectric liner, and
the first dielectric layer and the dielectric liner include different materials.
